(19) United States
(12) Patent Application Publication
(10) Pub. No.: US 2005/0254207 A1
(43) Pub. Date: Nov. 17, 2005

(54) Cooling means for a driver semiconductor

(75) Inventors: Chun-Kong Chan, Hsi Chih City (TW); Jeng-Shong Wang, Hsin Chuang (TW); Min-Chi Liu, Hsin Chuang (TW)

Correspondence Address: TROXELL LAW OFFICE PLLC, SUITE 1404, 5205 LEESBURG PIKE, FALLS CHURCH, VA, 22041, US

(73) Assignee: LIEN CHENG ELECTRONIC

(21) Appl. No.: 10/846,502

(22) Filed: May 17, 2004

(51) Int. Cl. H05K 7/20

(52) U.S. Cl. 361/688

(57) ABSTRACT

The cooling means for a driver semiconductor according to this invention is formed on a circuit board, which has a top side and a rear side. The front side of the circuit board is formed with a driver semiconductor that is soldered on the circuit board. The driver semiconductor has a plurality of input pins and output pins; at least a cooling element is conductively connected to the output pins of the driver semiconductor via the conductive layer on the back of the circuit board. In this way, when the driver semiconductor is overdriven, the produced heat energy is conducted from the output pins, through the conductive layer to the jumpers, radiated into the air and transmitted to the next electrical component.

### FIELD OF THE INVENTION

This invention refers to a cooling means for a driver semiconductor, and more particularly to a cooling means used for the driver semiconductor without a self-contained cooling metal fin.

### DESCRIPTION OF THE PRIOR ART

The driver IC (hereinafter, referred to as a driver semiconductor or power semiconductor), is the basis of electricity and electron techniques, and these electricity and electron techniques are oriented towards the applications of electricity or high power circuitries, where the electric energy is controlled and transformed by using power semiconductors and control techniques to supply power for various electrical devices, such as, for example, power supply devices, computer, system chip, and liquid crystal panels.

As the size of liquid crystal television or liquid crystal display increasingly become larger, a number of problems with driving a large panel, increasing the power of the backlight module and boosting the response of the panel, have to be faced for the driver semiconductor, so as to meet the requirement for large display size and high quality. In order to increase the transmission speed of the panel, the manufacturers, in addition to improving the liquid crystal material and panel manufacturing process, commonly use a driving method, called an overdrive, to improve the response speed of the liquid crystal panel, which is the most economic method. However, when the driver semiconductor is overdriven, heat dissipation increases and thus the temperature rises. There is thus a further need to take the problem of heat elimination into account.

In the prior art, in order to maintain the driver semiconductor at normal operating temperatures, a cooling fin is provided, and is integral to the driver semiconductor, during semiconductor packaging. Reference is made to FIG. 1, which illustrates an outer view of the conventional cooling means for a driver semiconductor. The driver semiconductor 9 has a packaging element 92 within which the chip is packaged, and a plurality of pins 94 connected to the chip for input and output of the power supply. On the side surface of the packaging element 92, a cooling metal fin 96 is placed against the chip for heat dissipation, thus enabling the driver semiconductor 9 to dissipate heat and maintain temperature within a normal operating range. However, the cost is high for the above described driver semiconductors with cooling fin, most of which are applied in driver semiconductors of large power.

In the aspect of backlight module, when the size of liquid crystal panel becomes larger, the load of the lamp of the backlight module is higher. Under an elevated ambient temperature, the driver semiconductor tends to exceed the upper limit of the operating temperature; there is not much cushion space. To solve this problem, some of the manufacturers have developed a double-side driving method to drive the liquid crystal panel of large capacitance. Although this method reduces half of the load of driver IC and decreases the power consumption, a double number of driver semiconductors is required on each panel.

Therefore, it is desirable for the manufacturers to enable the driver semiconductors to operate within a normal operating temperature range under a reasonable overload condition, with a cost less than that of the prior art.

Accordingly, this invention is provided to eliminate or reduce the above disadvantages with a reasonable design.

### SUMMARY OF THE INVENTION

It is the main object of the present invention to provide a cooling means for a driver semiconductor, and particularly a low-cost cooling means to enable the driver semiconductor to stay within a normal operating temperature range under a reasonable overload condition, particularly in the case of the application of liquid crystal panel.

It is another object of the present invention to provide a cooling means that directly utilizes the components commonly used for the existing circuit board, rather than a separately manufacture cooling means.

In order to achieve the main object, the present invention provides a cooling means for a driver semiconductor, which is formed on a circuit board for heat elimination of the driver semiconductor, comprising at least a cooling element that is made of metal and has at least two guide pins soldered to the circuit board and conductively connected to the output pins of the driver semiconductor.

In order to achieve the another object, the cooling element is a jumper made of metal wire.

In comparison with the prior art, the invention has the following advantages. Since cooling element is formed on the circuit board by soldering, especially the jumper used as cooling element, the cost is low and it is easy to assemble.

In the following, the invention will be described in greater detail in connection with preferred embodiments and with reference to the accompanying drawings, but the description is merely for illustrative purpose, without any limitation to the scope of the present.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is an outside view of a conventional cooling means for a driver semiconductor;

FIG. 2 is a top view of the first embodiment of the cooling means for a driver semiconductor according to the present invention;

FIG. 3 is a bottom view of the first embodiment of the cooling means for a driver semiconductor according to the present invention;

FIG. 4 is a top view of the second embodiment of the cooling means for a driver semiconductor according to the present invention; and

FIG. 5 is an application diagram of the cooling means for a driver semiconductor according to the present invention.

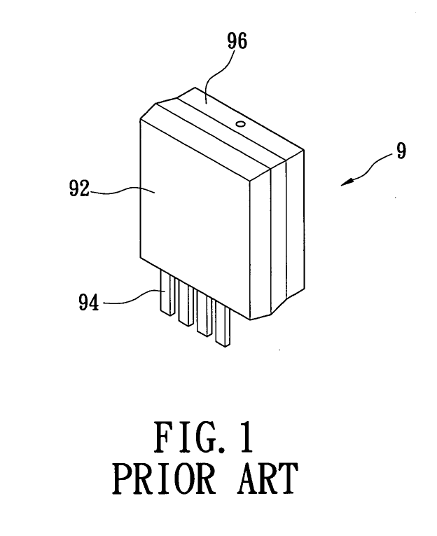

### DESCRIPTION OF THE PREFERRED EMBODIMENT

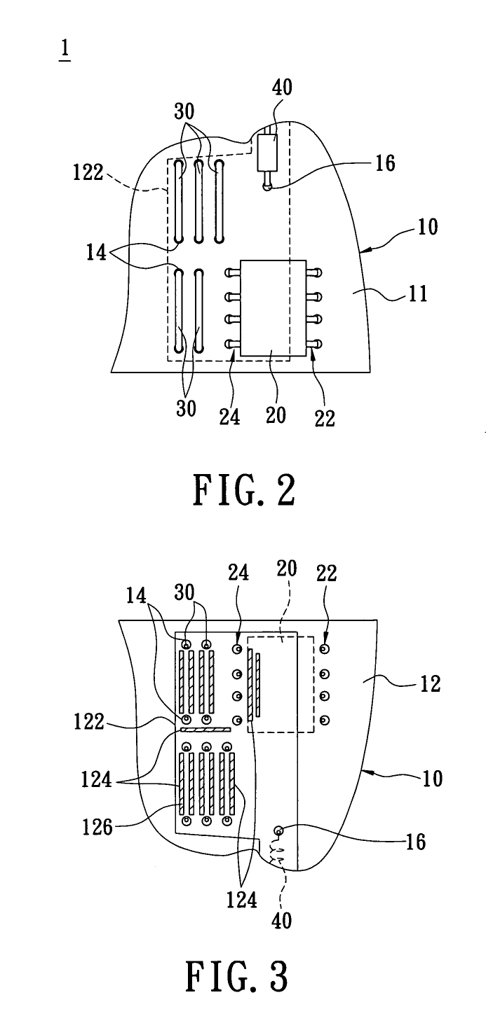

Reference is made to both FIGS. 2 and 3, which are a top view and bottom view of the cooling means for a driver semiconductor according to the present invention. The cooling means for a driver semiconductor according to this invention is formed on a circuit board 10. The circuit board 10 has a top side 1 (as illustrated in FIG. 2) and a rear side 12 (as illustrated in FIG. 3). The front side 11 of the circuit board 10 is formed with a driver semiconductor 20, which is soldered on the circuit board 10. The driver semiconductor 20 has a plurality of input pins 22 and output pins 24.

The cooling means according to this invention comprises at least one cooling element 30, which is made of metal, and preferably a metal with a good heat conductivity factor, such as aluminum, copper or other alloys. The cooling element is formed on the side of the driver semiconductor for heat elimination, and sandwiched between the driver semiconductor 20 and a next electrical component 40.

In this embodiment, the cooling element 30 is formed by a plurality of jumpers. Each jumper 30 has at least two pins soldered on the via hole 14 of the circuit board 10 in via drill manner, and conductively connected to the output pin 24 of the driver semiconductor 20 via a conductive layer 122 on the back of the circuit board 10. In this case, the plurality of jumpers 30 are arranged at one side of the driver semiconductor 20 in parallel, and the driver semiconductor 20 is formed on the front surface 11 of the circuit board 10.

In this way, when the driver semiconductor 20 is overdriven, the heat energy produced is conducted from the output pins 24, through the conductive layer 122 to the jumpers 30, and radiated into the air. Subsequently, the signals of the driver semiconductor 20 are electrically connected to the next electrical component 40.

This invention is elegantly conceived to use the jumpers 30 for heat elimination, in which the jumpers 30 are soldered on the same conductive layer 122 at both of their ends, instead of being connected to other components, thus enabling the heat produced by the driver semiconductor 20 to be radiated through the output pins 24 and the conductive layer 122, only for the purpose of heat elimination. Since the jumpers 30 are made of cheap metal wire with good conductivity, it avoids the need to manufacture separately a cooling device. The driver semiconductor 20 is thus provided with the cooling means at a low cost.

With reference to FIG. 3, to further improve cooling effect, the conductive layer 122 on the rear side 12 of the circuit board 10 is formed, with a plurality of clearance portions 124 without insulation coating. The clearance portions 124 are coated with a soldering tin 126 as a heat radiator. The soldering tin 126 also radiates the heat energy from the conductive layer 122 to the air to facilitate heat elimination. Since the output pins 24 are hot, the clearance portions 124 are formed at both sides of the driver semiconductor 20 on the back 12 of the circuit board 10 and coated with the soldering tin 126.

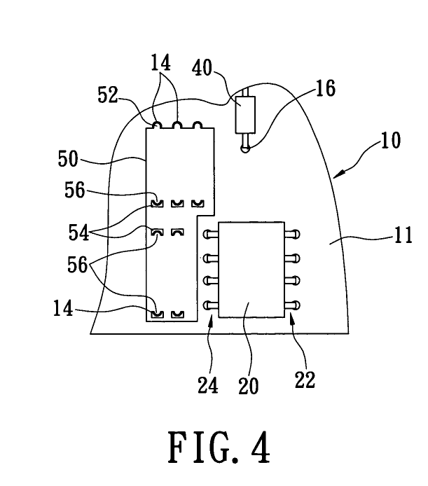

Reference is made to FIG. 4, which is a top view of the second embodiment of the cooling means for a driver semiconductor according to the present invention. Alternatively, the cooling element for a driver semiconductor according to this invention may be a metal sheet 50, thus broadening the heat radiating area. The metal sheet 50 is formed with a plurality of guide pins 52, 56 and soldered on the circuit board 10 in a via drill manner. For manufacturing convenience, the guide pins 52, 56 of the metal sheet 50 can be punched and bent to be integrated onto the metal sheet 50. The guide pins 52 can be formed as the edge of the metal sheet 50 by punching and bending process; the guide pins 56 in the middle of the metal board 50 can be formed by punching a plurality of punched holes 54 and then bending the inside edges of the punched holes 54 downward.

The metal sheet 50 can be secured on the circuit board 10 by soldering it on the circuit board 10 using surface mount techniques, where the bottom of the guide pins are slightly curved and arranged on the front surface 11 of the circuit board 10, and then passing it through the reflow oven (overflow) to solder it on the circuit board 10. In order to broaden heat radiating area of the metal sheet, the metal sheet may be undulating in shape.

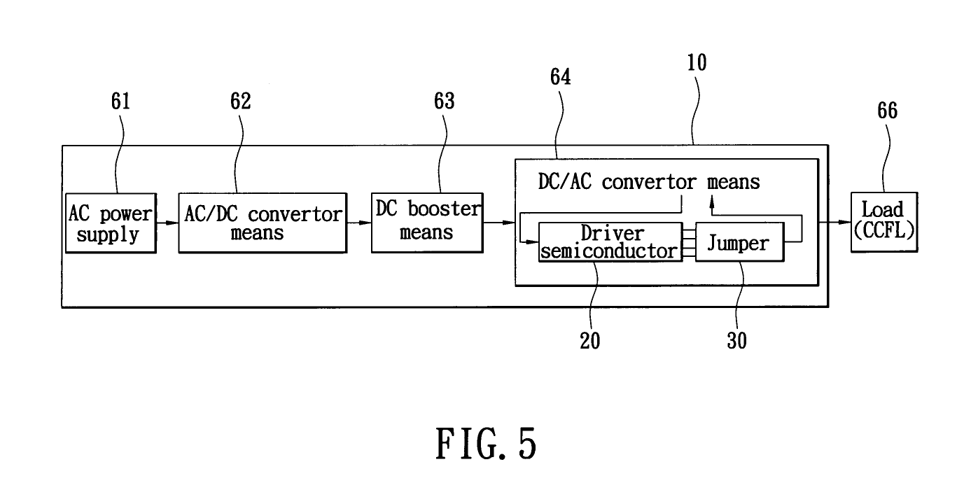

Reference is made to FIG. 5, which is a diagram of the application embodiment of the cooling means for a driver semiconductor according to the present invention. The circuit board 10 has an AC power supply socket 61 for connecting to the power supply, an AC/DC convertor means 62 for converting AC current into DC current, a DC booster means 63 for boosting DC current, and a DC/AC convertor means 64 for converting DC current into AC current suitable for a load 66. The load 66 may be a cold cathode fluorescent lamp within the backlight module of the liquid crystal panel. The driver semiconductor 20 and the cooling means 30 is formed inside the DC/AC convertor means 64, thus providing a heat elimination function if the load 66 increases.

The present invention provides a low-cost jumper or metal sheet as an additional cooling means for a driver semiconductor, so as to enable the driver semiconductor to stay within a normal operating temperature range under a reasonable overload condition.

This invention further improves heat elimination by forming the clearance portions on the back of the circuit board and coating with soldering tin. In this way, it is possible to enable the same circuit board, such as used for liquid crystal television or display, to drive large size of panel, and increase the power of the backlight module or boost the response speed of the panel to meet the requirement for large display size and high quality.

In comparison with the prior art, the cooling means for a driver semiconductor according to this invention can remarkably reduce manufacturing cost, especially during mass production of the circuit boards.

In conclusion, this invention fully meets the requirements for the patent application. Therefore, the application is proposed according to the patent law. While the preferred embodiments of this invention have disclosed above, they are not intended to limit the scope of this invention. Therefore the appended claims cover all such changes or modifications as fall within the spirit and scope of this present invention.

1. A cooling means for a driver semiconductor, formed on a circuit board for heat elimination, comprising:
at least a cooling element made of metal and including at least two guide pins soldered to the circuit board and conductively connected to output pins of the driver semiconductor.

2. The cooling means for a driver semiconductor according to claim 1, wherein the cooling element is a jumper made of metal wire.

3. The cooling means for a driver semiconductor according to claim 2, wherein the cooling means for a driver semiconductor has a plurality of jumpers formed on a side of the semiconductor in parallel.

4. The cooling means for a driver semiconductor according to claim 1, wherein the cooling element is placed on a same side of the circuit board as the driver semiconductor.

5. The cooling means for a driver semiconductor according to claim 1, wherein the cooling element is soldered on the circuit board in a via drill manner and conductively connected to a conductive layer on a back of the circuit board.

6. The cooling means for a driver semiconductor according to claim 1, wherein a conductive layer is formed on a back of the circuit board, and the conductive layer is formed with a plurality of clearance portions without insulation coating, wherein the plurality of clearance portions is coated with soldering tin for heat radiation.

7. The cooling means for a driver semiconductor according to claim 6, wherein clearance portions are formed at both ends of the output pins of the driver semiconductor on the back of the circuit board and coated with soldering tin.

8. The cooling means for a driver semiconductor according to claim 1, wherein the cooling means is a metal sheet formed with a plurality of guide pins soldered to the circuit board.

9. The cooling means for a driver semiconductor according to claim 8, wherein the plurality of guide pins of the metal sheet is formed integrally on the metal sheet by punching and bending processes.

10. The cooling means for a driver semiconductor according to claim 8, wherein the metal sheet is soldered on the circuit board using surface mount techniques.

11. The cooling means for a driver semiconductor according to claim 8, wherein the metal sheet is undulating in shape.
